(19) United States
(12) Patent Application Publication
(10) Pub. No.: US 2025/0301704 A1
(43) Pub. Date: Sep. 25, 2025

(54) SEMICONDUCTOR DEVICE INCLUDING GATE-CUT STRUCTURE FORMED AT EARLY STEP OF MANUFACTURING PROCESS

(71) Applicant: SAMSUNG ELECTRONICS CO., LTD., Suwon-si (KR)

(72) Inventors: Seung Min SONG, Halfmoon, NY (US); Kang-ill SEO, Springfield, VA (US)

(73) Assignee: SAMSUNG ELECTRONICS CO., LTD., Suwon-si (KR)

(21) Appl. No.: 18/782,661

(22) Filed: Jul. 24, 2024

Related U.S. Application Data
(60) Provisional application No. 63/569,541, filed on Mar. 25, 2024.

(51) Int. Cl. H01L 29/423; H01L 21/8234; H01L 27/088; H01L 29/06; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 64/017; H10D 84/0128; H10D 84/013; H10D 84/0135; H10D 84/0151; H10D 84/038; H10D 84/83

(57) ABSTRACT

Provided is a semiconductor device which includes: a 1^{st} gate structure; a 2^{nd} gate structure at a side of the 1^{st} gate structure in a 2^{nd} direction crossing a 1^{st} direction; an isolation structure below the 1^{st} gate structure and the 2^{nd} gate structure in a 3^{rd} direction crossing the 1^{st} direction and the 2^{nd} direction; and a gate-cut structure between the 1^{st} gate structure and the 2^{nd} gate structure, wherein a width of the gate-cut structure in the 2^{nd} direction increases in the 3^{rd} direction from a level of a top surface of the 1^{st} gate structure or the 2^{nd} gate structure to a level of a bottom surface of the isolation structure.

### CROSS-REFERENCE TO RELATED APPLICATION

This application is based on and claims priority from U.S. Provisional Application No. 63/569,541 filed on Mar. 25, 2024 in the U.S. Patent and Trademark Office, the disclosure of which is incorporated herein in its entirety by reference.

### BACKGROUND

### 1. Field

Apparatuses and methods consistent with the disclosure relate to a semiconductor device including a gate-cut structure which is formed at an early step of a process of manufacturing the semiconductor device.

### 2. Description of Related Art

In a process of manufacturing a semiconductor device, a gate-cut structure is formed to divide a single-extended gate structure into separate gate structures for individual transistors or transistor units. As demands for a semiconductor device having a high device density as well as a high device performance increase, formation of a gate-cut structure requires a high-level process precision to save a process margin for subsequent steps of manufacturing the semiconductor device.

FIGS. 1A-1C illustrate a semiconductor device of a nanosheet transistor structure in which a gate-cut structure is formed.

FIG. 1A is a plan view of a semiconductor device 10, and FIGS. 1B and 1C are cross-section views of the semiconductor device 10 shown in FIG. 1A taken along lines I-I′ and II-II′ thereof, respectively.

It is to be understood here that FIG. 1A is provided to show a positional

relationship between selected structural elements of the semiconductor device 10, and thus, some structural elements such as a substrate and an isolation structure shown in FIGS. 1B and 1C are not shown in FIG. 1A. As shown in FIGS. 1A-1C, a D1 direction is a channel-length direction in which a current flows between two source/drain patterns (or source/drain regions) of a transistor connected to each other through a channel structure, a D2 direction is a channel-width direction that crosses the D1 direction, and a D3 direction is a vertical direction that crosses the D1 and D2directions both of which are horizontal directions.

Referring to FIGS. 1A-1C, the semiconductor device 10 may include a 1^{st} active pattern AP1 and a 2^{nd} active pattern AP2 extended in a D1 direction and arranged in a D2 direction on a substrate 101. Each of the active patterns AP1 and AP2 may be formed on the substrate 101 in a protrusion form, and a 1^{st} isolation structure 110 may be formed at D2-direction sides of the active patterns AP1 and AP2, including a region between the active patterns AP1 and AP2. The isolation structure 110 may also be referred to as a shallow trench isolation (STI) structure as this isolation structure is formed in a shallow trench T formed by a top surface of the substrate 101 and respective side surfaces of the two active patterns AP1 and AP2. The semiconductor device 10 may also include a plurality of gate structures G1-G5 extended in the D2 direction to cross the active patterns AP1 and AP2, and arranged in the D1 direction at a predetermined pitch. A gate spacer 115 may be formed on side surfaces of each of the gate structures G1-G5 as shown in FIG. 1A.

Among the gate structures G1-G5, each of the gate structures G2-G4 may be divided into two gate structures by a gate-cut structure CT so that these two gate structures are isolated from each other. For example, the respective gate-cut structures CT may divide the gate structure G2 into a 1^{st} gate structure G21 and a 2^{nd} gate structure G22, the gate structure G3 into a 1^{st} gate structure G31 and a 2^{nd} gate structure G32, and the gate structure G4 into a 1^{st} gate structure G41 and a 2^{nd} gate structure G42.

On each of the active patterns AP1 and AP2 may be formed a channel structure surrounded by a corresponding gate structure among the gate structures G1-G5. For example, a 1^{st} channel structure CH1 may be formed on the 1^{st} active pattern AP1 and surrounded by the 1^{st} gate structure G21 with a gate dielectric layer 118 therebetween, and a 2^{nd} channel structure CH2 may be formed on the 2^{nd} active pattern AP2 and surrounded by the 2^{nd} gate structure G22 with the gate dielectric layer 118 therebetween. Although not shown in FIGS. 1A-1C, source/drain patterns may be formed on D1-direction sides of each of the channel structures CH1 and CH2 above the active patterns AP1 or AP2 to form a transistor along with each of the channel structures CH1 and CH2 and each of the 1^{st} gate structure G21 and the 2^{nd} gate structure G22, respectively. Each of the channel structures CH1 and CH2 may include a plurality of channel layers 104 connecting the source/drain patterns at sides thereof in the D1 direction to form the corresponding transistor as a nanosheet transistor which is also referred to as a gate-all-around (GAA) transistor, or as a multi-bridge channel field-effect transistor (MBCFET).

A 2^{nd} isolation structure 120 may be formed above the 1^{st} isolation structure 110 between the gate structures G1-G5 and between the source/drain patterns of the channel structures including the channel structures CH1 and CH2 to isolate these transistor structures from each other.

The substrate 101 including the active patterns AP1 and AP2 may be formed of silicon (Si) although it may include other materials such as silicon germanium (SiGe), silicon carbide (SiC), not being limited thereto. The channel layers 104 of the structures CH1 and CH2 may be formed of the same material forming the substrate 101, for example, silicon (Si) or silicon germanium (SiGe).

The gate structures G1-G5 may be formed of a work-function metal layer surrounding the gate dielectric layer 118 and a gate electrode surrounding the work-function metal layer. The gate dielectric layer 118 may include an interfacial layer formed of an oxide material such as silicon oxide (e.g., SiO, SiO₂, etc.) and/or silicon oxynitride (e.g., SiON), and a high-k layer formed of a high-k material such as hafnium (Hf), aluminum (Al), zirconium (Zr), lanthanum (La), magnesium (Mg), barium (Ba), titanium (Ti), lead (Pb), and/or a combination thereof, not being limited thereto. The work-function metal layer may be formed a metal such as TiN, WN, TiAl, TiAlN, TaN, TiC, TaC, TiAlC, TaCN, TaSiN, and/or a combination thereof, not being limited thereto, and the gate electrode may include a metal material such as Cu, W, Al, ruthenium (Ru), molybdenum (Mo), Co, and/or a combination thereof, not being limited thereto.

The gate spacer 115 may be formed of silicon oxide or silicon nitride (e.g., SiO₂, SiN, SiBCN, SiCN, SiOC, SiOCN, etc.), not being limited thereto. The gate-cut structure CT may be formed of a dielectric material such as silicon nitride or its composite (SiN, Si₃N₄, SiCN, SiBCN, etc.,) not being limited thereto. The 1^{st} isolation structure 110 and the 2^{nd} isolation structure 120 may be formed of a low-k dielectric material such as silicon oxide (e.g., SiO₂, etc.).

In the meantime, the formation of the gate-cut structures CT is performed after the 2^{nd} isolation structure 120 isolating the source/drain patterns are formed and the gate structures G1-G5 are formed to replace a dummy gate structure at the same position in an intermediate structure of the semiconductor device 10. At this time of forming the gate-cut structures CT, because of patterning variations of a high-aspect-ratio etching operation on each of the gate structures G2-G4 to form recesses R0 and a subsequent deposition of the dielectric material in the recesses to form the gate-cut structures CT, a loss of the low-k dielectric material may occur at the 2^{nd} isolation structure 120 around the recesses. Thus, an excess material EX of the gate-cut structure CT filling the recesses may be formed at the positions of the dielectric material loss, which makes formation of a gate contact structure on any of the gate structures G2-G4 difficult and complicated.

Further, as a width W0 of the recess R0 is formed to become smaller in the D3 direction from a top surface to a bottom surface thereof, that is, from a level of a top surface to a bottom surface of the gate structure G2 because of the general etching characteristic of a negative-slope profile, a width of the gate-cut structure CT, which is the same as the width W0 of the recess R0, may also become smaller to have a negative slope at a side surface thereof in the same D3 direction. Thus, a residue RE of a metal forming the gate structures G2-G4 may remain between a lower portion of at least one of the respectively gate-cut structures CT and the gate spacer 115, which may degrade an isolation property of the gate-cut structure CT.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

According to an aspect of example embodiments, there is provided a semiconductor device which may include: a 1^{st} gate structure; a 2^{nd} gate structure at a side of the 1^{st} gate structure in a 2^{nd} direction crossing a 1^{st} direction; an isolation structure below the 1^{st} gate structure and the 2^{nd} gate structure in a 3^{rd} direction crossing the 1^{st} direction and the 2^{nd} direction; and a gate-cut structure between the 1^{st} gate structure and the 2^{nd} gate structure, wherein a width of the gate-cut structure in the 2^{nd} direction increases in the 3^{rd} direction from a level of a top surface of the 1^{st} gate structure or the 2^{nd} gate structure to a level of a bottom surface of the isolation structure.

According to an aspect of example embodiments, there is provided a semiconductor device which may include: a 1^{st} channel structure on the 1^{st} active pattern; a 1^{st} gate structure on the 1^{st} channel structure; and a gate-cut structure in the 1^{st} gate structure, at a side of the 1^{st} channel structure in a 2^{nd} direction crossing a 1^{st} direction, wherein the gate-cut structure has a same width as the 1^{st} channel structure in the 2^{nd} direction, at a same level in a 3^{rd} direction crossing the 1^{st} direction and the 2^{nd} direction.

According to an aspect of example embodiments, there is provided a semiconductor device which may include: a plurality of gate structures arranged in a 1^{st} direction and extended in a 2^{nd} direction crossing the 2^{nd} direction; and a gate-cut structure continuously extended in the 1^{st} direction and dividing each of the plurality of gate structures into a 1^{st} gate structure and a 2^{nd} gate structure.

According to an aspect of example embodiments, there is provided a semiconductor device which may include: a 1^{st} gate structure; a 2^{nd} gate structure at a side of the 1^{st} gate structure in a 2^{nd} direction crossing a 1^{st} direction; an isolation structure below the 1^{st} gate structure and the 2^{nd} gate structure in a 3^{rd} direction crossing the 1^{st} direction and the 2^{nd} direction; and a gate-cut structure between the 1^{st} gate structure and the 2^{nd} gate structure, wherein the gate-cut structure penetrates through the isolation structure to reach below a level of a bottom surface of the isolation structure in the 3^{rd} direction.

According to an aspect of example embodiments, there is provided a method of manufacturing a semiconductor device, which may include: forming a plurality of channel structures on a substrate arranged in a 2^{nd} direction crossing a 1^{st} direction; removing a channel structure among the plurality of channel structures; forming a gate-cut structure in a space provided by the removing the channel structure; and forming at least one gate structure on the channel structure and the gate-cut structure.

### BRIEF DESCRIPTION OF DRAWINGS

Example embodiments of the disclosure will be more clearly understood from the following detailed description taken in conjunction with the accompanying drawings.

FIGS. 1A-1C illustrate a semiconductor device of a nanosheet transistor structure in which a gate-cut structure is formed.

FIGS. 2A-2C illustrate a semiconductor device including a gate-cut structure formed at an early step of manufacturing the semiconductor device, according to one or more other embodiments.

FIGS. 3A through 3J illustrate cross-section views of intermediate semiconductor devices after respective steps of manufacturing a semiconductor device including a gate-cut structure formed at an early step of manufacturing the semiconductor device, according to one or more other embodiments.

FIG. 4 illustrates a flowchart of a method of manufacturing a semiconductor device including a forksheet transistor structures and a gate cut structure, according to one or more other embodiments.

FIG. 5 is a schematic block diagram illustrating an electronic device including a semiconductor device including a forksheet transistor structure and a gate cut structure, according to one or more embodiments.

### DETAILED DESCRIPTION

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, active (channel) layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, for example, a 1^{st} element or a 1^{st} direction discussed in the description of an embodiment could be termed a 2^{nd} element or a 2^{nd} direction in a claim without departing from the teachings of the disclosure. As another example, a 1^{st} element or a 1^{st} direction discussed in a claim could be termed a 2^{nd} element or a 2^{nd} direction in another claim having no dependency therebetween without departing from the teachings of the disclosure.

As used herein, expressions such as “at least one of,” when preceding a list of elements, modify the entire list of elements and do not modify the individual elements of the list. For example, the expression, “at least one of a, b and c” and “at least one of a, b or c” should be understood as including only a, only b, only c, both a and b, both a and c, both b and c, or all of a, b and c. Herein, when a term “same” is used to compare a dimension of two or more elements, the term may cover a “substantially same” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor or a forksheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments.

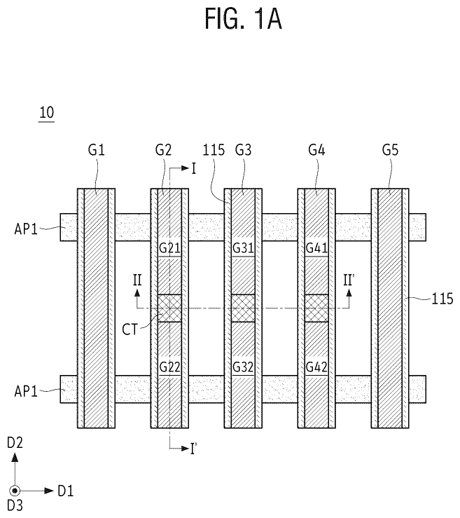

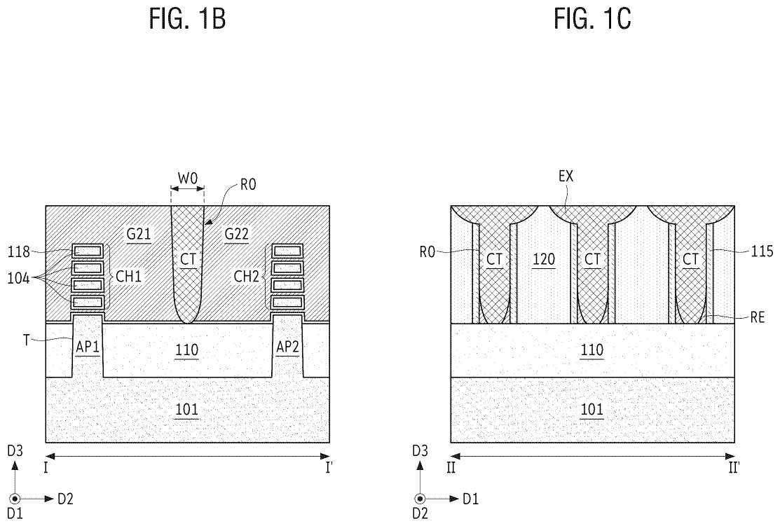

Herebelow, various embodiments provide herebelow a structure of a semiconductor device including an extended gate structure formed at an earlier step of manufacturing the semiconductor device to address problems of the gate structures in the semiconductor device 10 of FIGS. 1A-1C.

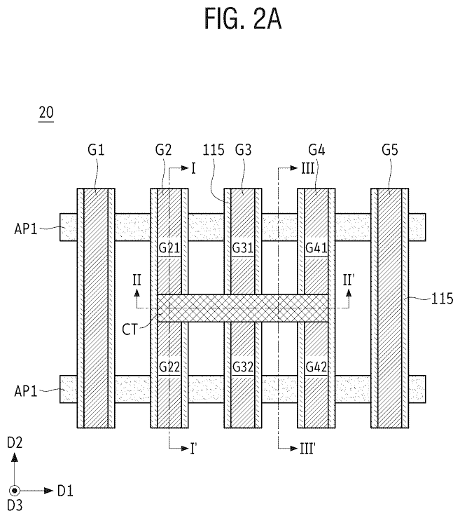

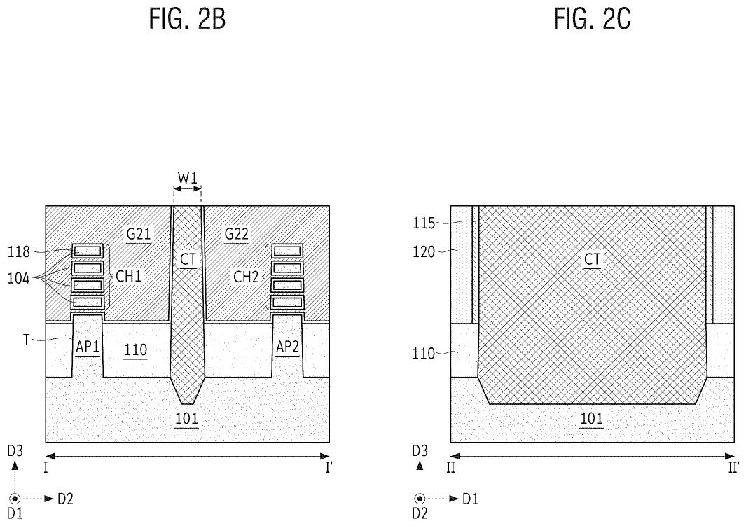

FIGS. 2A-2C illustrate a semiconductor device including a gate-cut structure formed at an early step of manufacturing the semiconductor device, according to one or more other embodiments.

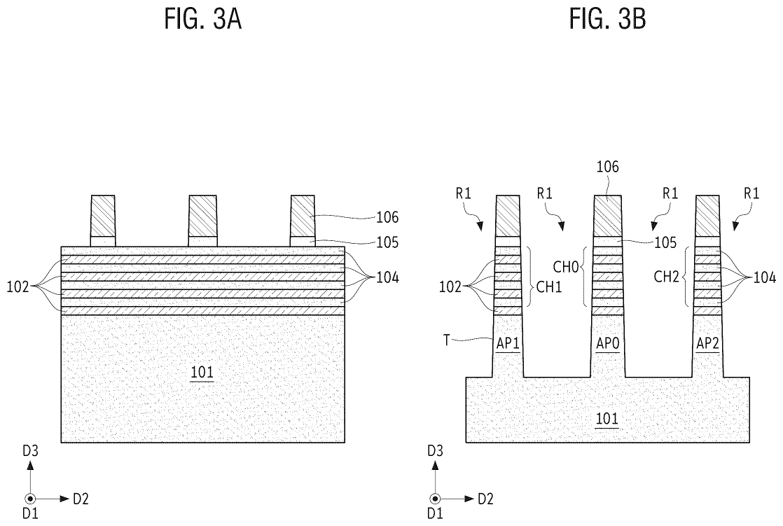

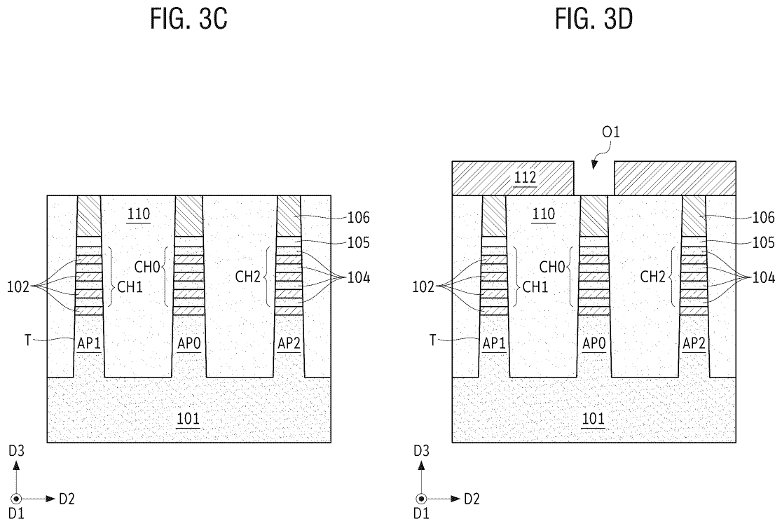

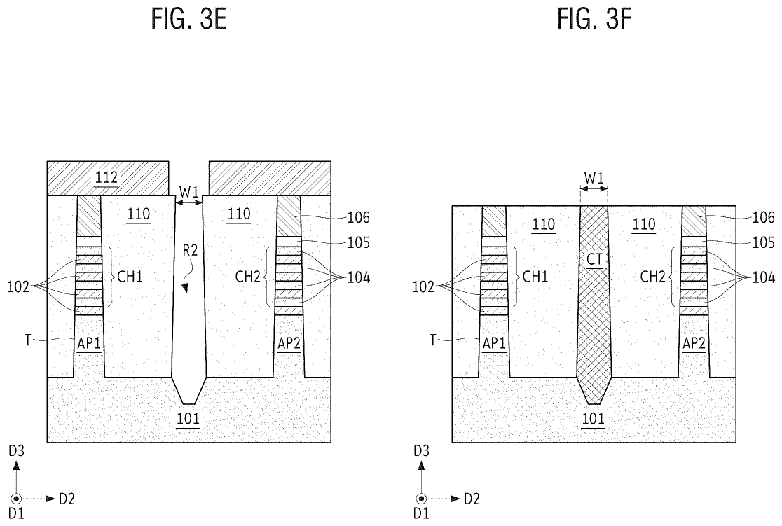

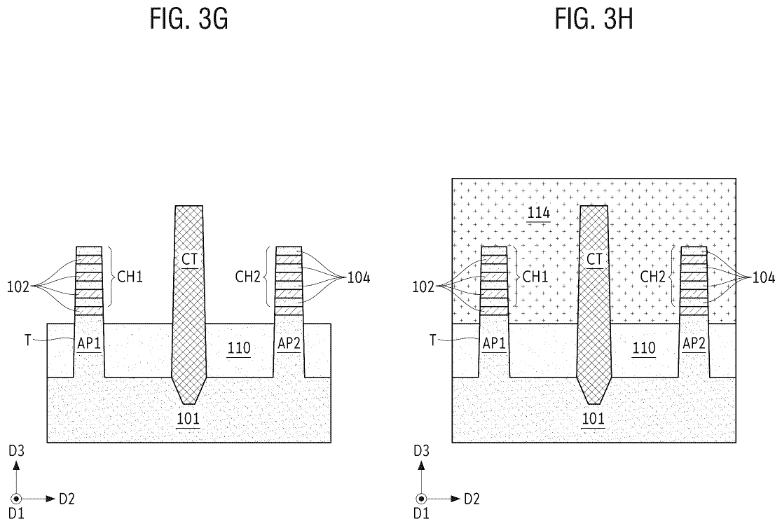

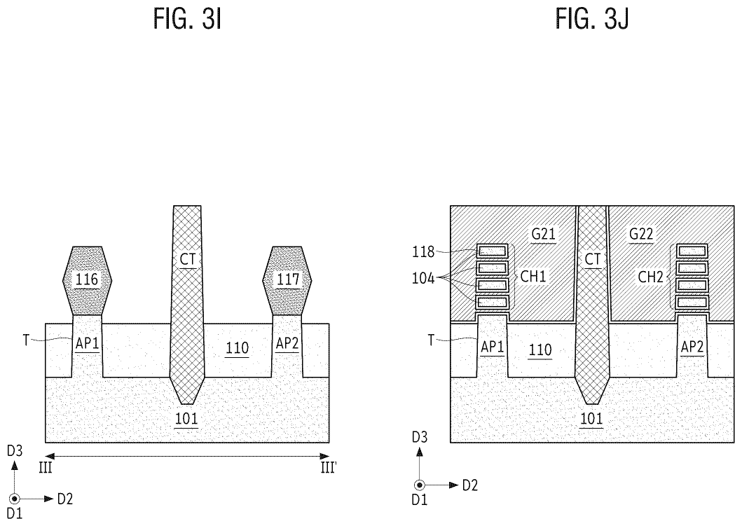

FIG. 2A is a plan view of a semiconductor device 210, and FIGS. 1B and 1C are cross-section views of the semiconductor device 10 shown in FIG. 1A taken along lines I-I′ and II-II′ thereof, respectively. A cross-section view of the semiconductor device 10 along a line III-III′ is shown in FIG. 3I, and will be described later in reference to FIGS. 3A-3K.

Referring to FIGS. 2A-2C respectively corresponding to FIGS. 1A-1C, a semiconductor device 20 may have the same structural elements as those of the semiconductor device 10 of FIGS. 1A-1C, and thus, while duplicate descriptions may be omitted, different aspects of the semiconductor device 20 will be described herebelow. It is to be also understood that the same reference characters and numerals shown in FIGS. 1A-1C may be used herebelow in describing the semiconductor device 20.

In the semiconductor device 20, a gate cut structure CT may have been formed in an early step of manufacturing the semiconductor device 20, as will be described in reference to FIGS. 3A-3K later, before the following structural elements are formed: source/drain patterns, a 2^{nd} isolation structure 120, and a dummy gate structure 114 to be replaced by gate structures G1-G5. Thus, the material loss occurring to the 2^{nd} isolation structure 120 when the gate contact structure CT is formed (FIG. 1C) and the formation of the excess material EX of the gate-cut structure CT may be avoided. Further, the metal residue RE of the gate structures G2-G4 (FIG. 1C) that diminishes the isolation properties of the gate-cut structure CT may not remain in a recess for the gate-cut structure CT in semiconductor device 20.

Further, the gate-cut structure CT in the semiconductor device 20 may have been formed by removing and replacing a dummy channel structure CH0 and a dummy active pattern AP0 therebelow which are formed between a combination of a 1^{st} active pattern AP1 and a 1^{st} channel structure CH1 and a combination of a 2^{nd} active pattern AP2 and a 2^{nd} channel structure CH2 as will also be described in reference to FIGS. 3A-3K later. As the positions of the two active patterns AP1, AP2 and the dummy active pattern AP0 may be early determined in manufacturing the semiconductor device 20, it may be easy to control or determine a position of the gate-cut structure CT between the combination of the 1^{st} active pattern AP1 and the 1^{st} channel structure CH1 and the combination of the 2^{nd} active pattern AP2 and the 2^{nd} channel structure CH2, thereby to facilitate the manufacturing process of the semiconductor device 20.

In comparison with the profile of the gate-cut structure CT in the semiconductor device 10 having a negative slope at the side surface thereof in the D3 direction from the level of a top surface to the level of the gate structure G2, a profile of the gate-cut structure CT in the semiconductor device 20 may have a positive slope at a side surface thereof at least above a level of a top surface of the substrate 101 which may be coplanar or aligned with a bottom surface of the 1^{st} isolation structure 110. For example, while the width W0 of the gate contact structure CT in the semiconductor device 10 becomes smaller downward in the D3 direction toward the level of the bottom surface of the gate structures G2-G4, a width W1 of the gate contact structure CT in the semiconductor device 20 becomes greater in the same D3 direction.

This positive-slope side surface of the gate-cut structure CT in the semiconductor device 20 may be obtained because the gate-cut structure CT is formed in the semiconductor device 20 by replacing the dummy channel structure CH0 which may have the same structural shape and positive-slope side surfaces as the channel structures CH1 and CH2. In contrast, the gate-cut structure CT of the semiconductor device 10 may be formed by simply patterning each of the gate structures G2-G4, in which case the width W0 of the recess R0 formed by the gate structure patterning becomes smaller downward in the D3 direction as shown in FIG. 1B.

Due to the positive-slope side surface of the gate-cut structure CT, a space between an upper portion of the gate-cut structure CT and the an upper portion of each of the channel structures including the channel structures CH1 and CH2 becomes greater in the D2 direction to provide an area gain to the semiconductor device 20.

In the meantime, the gate-cut structure CT in the semiconductor device 20 may be formed to penetrate through the 1^{st} isolation structure 110 formed between the active patterns AP1 and AP2 into an upper portion of the substrate 101 in the D3 direction. Here, a portion of the gate-cut structure CT penetrating into the substrate 101 may have a negative slope in which a width of the gate-cut structure CT decreases in the D3 direction toward a bottom surface of the substrate 101. This is because the dummy active pattern AP0 replaced by the gate-cut structure CT is not formed below the top surface of the substrate 101. Thus, this portion of the gate-cut structure CT may have to be formed by patterning the substrate 101 from the top surface thereof, in which case the gate-cut structure CT may well have a negative-slope profile in the substrate 101. Nonetheless, this portion of the gate-cut structure CT penetrating into the substrate 101 may provide a structural strength to the gate-cut structure CT with respect to the adjacent structural elements such as the gate structures G2-G4.

The profiles of the channel structures CH1, CH2, CH0, and the gate-cut structure CT may not limited to the above-described positive-slope profile. According to one or more other embodiments, the width of each of the channel structures CH1, CH2 and CH0 may be the same along the D3 direction, and thus, the.

In addition, the gate-cut structure CT may be formed in the semiconductor device 20 before the channel structures CH1 and CH2 and the dummy channel structure CH0 with the dummy active pattern AP0 therebelow which are extended in the D1 direction are patterned to form the source/drain patterns on the channel structures CH1 and CH2. Thus, the gate-cut structure CT may be formed to be continuously extended in the D1 direction across the gate structures G2-G4. The gate-cut structure CT extended in the D1 direction across the gate structures G2-G4 may suppress expansion of the source/drain patterns in the D2 direction when these source/drain patterns are epitaxially grown from the channel structures CH1 and CH2, thereby providing additional isolation properties between the source/drain patterns formed on the 1^{st} active pattern AP1 and the source/drain patterns formed on the 2^{nd} active pattern AP2.

As described above, the gate-cut structure CT in the semiconductor device 20 may be formed before the gate structure G1-G5 are formed, and thus, a gate dielectric layer 118 surrounding a plurality of channel layers 104 of the channel structures may be extended to be formed on side surfaces of the gate-cut structure CT.

Also, as described above, the gate-cut structure CT in the semiconductor device 20 may be formed by replacing the dummy channel structure CH0 and the dummy active pattern AP0 therebelow, and thus, the width W1 of the gate-cut structure CT may be the same as a width of the dummy channel structure CH0 and the dummy active pattern AP0 therebelow at a same level in the D3 direction, which can be the same as a width of the 1^{st} channel structure CH1 and the 1^{st} active pattern AP1 therebelow and a width of the 2^{nd} channel structure CH2 and the 2^{nd} active pattern AP2 therebelow, at a same level in the D3 direction. However, the disclosure is not limited thereto. The width W1 of the gate-cut structure Ct may be controlled by differentiating the width of the dummy channel structure CH0 and the dummy active pattern AP0 therebelow from the width of the 1^{st} channel structure CH1 and the 1^{st} active pattern AP1 therebelow and a width of the 2^{nd} channel structure CH2 and the 2^{nd} active pattern AP2 therebelow.

Herebelow, a method of manufacturing the semiconductor device 20 is provided.

FIGS. 3A through 3J illustrate cross-section views of intermediate semiconductor devices after respective steps of manufacturing a semiconductor device including a gate-cut structure formed at an early step of manufacturing the semiconductor device, according to one or more other embodiments.

The semiconductor device manufactured in reference to FIGS. 3A-3J may be the semiconductor device 20 shown in FIGS. 2A-2C, and the cross-section view of each of the intermediate semiconductor devices shown in FIGS. 3A-3J may correspond to that shown in FIG. 2A. Thus, duplicate descriptions about the same structural elements described above in reference to FIG. 2 may be omitted, and the same reference characters or numerals may be used herebelow.

Referring to FIG. 3A, an intermediate semiconductor device, which is an initial channel structure, including a plurality of nanosheet layers may be formed on a substrate 101, and 1^{st} hard mask patterns 106 and respective protection layers 105 therebelow, respectively, may be formed at positions below which respective channel structures and active patterns are to be formed.

The intermediate semiconductor device may be formed by, for example, epitaxially growing a plurality of nanosheet layers from the substrate 101 in the D3 direction. The epitaxy performed in this step may include molecular beam epitaxy (MBE), vapor-phase epitaxy (VPE), etc. such that a sacrificial layer 102 is first grown, and then, a channel layer 104 is grown one after another in an alternating manner until a desired number of the nanosheet layers are obtained. The channel layers 104 may each be formed of silicon (Si), and the sacrificial layers 102 may each be formed of silicon germanium (SiGe).

Subsequently, a protection layer and a hard mask layer thereon may be formed on an uppermost channel layer 104 and patterned to form the hard mask patterns 106 and the protection layers 105 therebelow through, for example, photolithography and etching operations. The protection layers 105 may be formed of an oxide material (e.g., SiO, SiO₂, etc.), and the hard mask patterns 106 may be formed of a nitride material (e.g., SiN, Si₃N₄, etc.), not being limited thereto. The protection layers 105 may be formed to protect the uppermost channel layer 104 from the formation of the 1^{st} hard mask patterns 106 through the photolithography and etching operations.

The hard mask patterns 106 and the protection layers 105 therebelow may be arranged in the D2 direction so that respective channel structures and active patterns are to be patterned in the D2 direction.

Referring to FIG. 3B, the intermediate semiconductor device obtained in the previous step (FIG. 3A) may be patterned based on the 1^{st} hard mask patterns 106 to form a 1^{st} channel structure CH1 with a 1^{st} active pattern AP1 therebelow, a dummy channel structure CH0 with a dummy active pattern AP0 therebelow, and a 2^{nd} channel structure CH2 with a 2^{nd} active pattern AP2 therebelow.

Dry etching (e.g., reactive ion etching (RIE)), not being limited thereto, may be performed on the intermediate semiconductor device of FIG. 3A based on the 1^{st} hard mask patterns 106 to form the channel structures CH1, CH0 and CH2 with the active patterns AP1, AP0 and AP2, respectively, therebelow extended in the D1 direction.

With the formation of these combinations of a channel structure and an active pattern, a plurality of recesses R1 may be formed therebetween. Lower portions of the recesses R1 between the active patterns AP1, AP0 and AP2 may be referred to as shallow trenches T, and a bottom surface of the shallow trenches T may form a top surface of the substrate 101.

Here, according to the general etching characteristic of a negative profile, each of the recesses R1 including the shallow trenches T may take a negative-slope profile in which a width of the recess R1 becomes smaller downward in the D3 direction. Accordingly each of the channel structures CH1, CH0 and CH2 with the active patterns AP1, AP0 and AP2 respectively therebelow may have a positive-slope profile in which a width thereof becomes greater in the same D3 direction.

The dummy channel structure CH0 and the dummy active pattern AP0 are referred to as such because these structures as placeholder structures for a gate-cut structure CT will be removed and the gate contact structure will be formed at a space obtained by the removal of these structures in later steps (FIGS. 3E and 3F).

Referring to FIG. 3C, an isolation material may be filled in the recesses R1 including the shallow trenches T to form a 1^{st} isolation structure 110.

The formation of the 1^{st} isolation structure 110 may be performed by, for example, depositing a low-k dielectric material such as silicon oxide (e.g., SiO, SiO₂, etc.) through, for example, physical vapor deposition (PVD), chemical vapor deposition (CVD), plasma-enhanced chemical vapor deposition (PECVD), or a combination thereof, not being limited thereto, followed by planarization such as chemical-mechanical polishing (CMP).

Referring to FIG. 3D, 2^{nd} hard mask patterns 112 may be formed on a top surface of the intermediate semiconductor device obtained in the previous step (FIG. 3C) to expose a top surface of the 1^{st} hard mask pattern 106 formed on the dummy channel structure CH0.

The 2^{nd} hard mask patterns 112 may be formed by depositing a material such as silicon oxide (e.g., SiO, SiO₂, etc.) through, for example, another photolithography and etching operations to expose, through an opening O1, the top surface of the 1^{st} hard mask pattern 106 formed on the dummy channel structure CH0.

The opening O1 between the 2^{nd} hard mask patterns 112 may be formed to expose only a portion of the top surface of the 1^{st} hard mask pattern 106 on the dummy channel structure CH0 by a predetermined length in the D1 direction. Here, the predetermined length of the opening O1 may be or correspond a length of the gate-cut structure CT in the D1 direction across the gate structures G2-G4 as shown in FIG. 2A.

Referring to FIG. 3E, a 2^{nd} recess R2 may be formed to penetrate through the 1^{st} isolation structure 110 down into the substrate 101.

The 2^{nd} recess R2 may be formed through, for example, dry etching and/or wet etching which removes the dummy channel structure CH0 and the dummy active pattern AP0 therebelow. This etching operation may continue to remove an upper portion of the substrate 101 below the dummy active pattern AP0.

Here, as a width W1 of the 2^{nd} recess R2 may become greater downward from a level of a top surface to a level of a bottom surface of the 1^{st} isolation structure 110, and becomes smaller from a level of the top surface to a level of a bottom surface of the substrate 101. This is because the 2^{nd} recess R2 may be formed by removing the dummy channel structure CH0 and the dummy active pattern AP0 having a positive-slope profile as described earlier (FIG. 3B), and a negative-slope profile of a lower portion of the 2^{nd} recess inside the substrate 101 may be formed by the general etching characteristic.

Further, a length of the 2^{nd} recess R2 in the D1 direction may be the same as the predetermined length in the D1 direction of the top surface of the 1^{st} hard mask pattern 106 on the dummy channel structure CH0 exposed by the 2^{nd} hard mask patterns 112.

Referring to FIG. 3F, a gate contact structure CT may be formed in the 2^{nd} recess R2, and the 2^{nd} hard mask patterns 112 may be removed.

As the gate-cut structure CT may be formed in the 2^{nd} recess R2, the gate-cut structure CT may have the same structural shape or form as the 2^{nd} recess R2. For example, a width W1 of the gate-cut structure CT may become greater downward in the D3 direction until the level of the top surface of the substrate 101 and become smaller downward in the same D3 direction therefrom. Further, a length of the gate-cut structure CT in the D1 direction may be the same as the length of the 2^{nd} recess R2 in the D1 direction, which may correspond to or be the length of the gate-cut structure CT in the D1 direction across the gate structures G2-G4 as shown in FIG. 2A.

The formation of the gate contact structure CT may be performed by depositing an isolation material such as silicon nitride (e.g., SiN, Si₃N₄, SiBCN, SiCN, etc.) in the 2^{nd} recess R2 including the lower portion penetrating into the substrate 101 through, for example, PVD, CVD, PECVD or a combination thereof, not being limited thereto. The removal of the 2^{nd} hard mask patterns 112 may be performed through, for example, ashing or stripping, not being limited thereto.

Referring to FIG. 3G, the 1^{st} isolation structure 110 may be patterned such that a top surface thereof is at a level below or at a level of a top surface of the active pattern AP1 or AP2 to form a shallow trench isolation (STI) structure extended in the D1 direction, and the 1^{st} hard mask patterns 106 with the respective protection layers 105 therebelow may be removed.

The 1^{st} isolation structure 110 patterned in this step may be referred to as an STI structure. The removal of the 1^{st} hard mask patterns 106 with the protection layers 105 therebelow may be performed through, for example, ashing or stripping.

Referring to FIG. 3H, a dummy gate structure 114 may be formed to surround the 1^{st} channel structure CH1 with the 1^{st} active pattern AP1 therebelow and the 2^{nd} channel structure CH2 with the 2^{nd} active pattern AP2 therebelow.

The dummy gate structure 114 may be formed to reserve a space for a gate structure to be formed in a later step (FIG. 3J) and provide a structural support for formation of source/drain patterns in a next step (FIG. 3I). The dummy gate structure 150D may be formed by, for example, PVD, CVD, PECVD or a combination thereof followed by planarization at a top surface thereof. The dummy gate structure 150D may include a material such as polycrystalline silicon (p-Si) or amorphous silicon (a-Si).

Referring to FIG. 3I, 1st source/drain patterns 116 may be formed on the 1^{st} channel structure CH1 and 2^{nd} source/drain patterns 117 may be formed on the 2^{nd} channel structures CH2.

In this step, the channel structures CH1 and CH2 extended in the D1 direction with the dummy gate structure 114 thereon may be patterned in the D1 direction to form spaces for source/drain patterns based on photolithography, masking and etching, and then, the source/drain patterns 116 and 117 may be epitaxially grown from the channel layers 104 in the channel structures CH1 and CH2. At this time, the sacrificial layers 102 in the channel structures CH1 and CH2 may be blocked by respective inner spacers. It is understood here that FIG. 3I is a cross-section view taken along the line III-III′ shown in FIG. 2A.

When the channel structures CH1 and CH2 are patterned in the D1 direction to form the spaces for the formation of the source/drain patterns 116 and 117 therein, the dummy gate structure 114 surrounding the channel structures CH1 and CH2 may also be patterned such that the patterned channel structures CH1 and CH2 may also be surrounded by the respectively patterned dummy gate structures 114. However, the gate-cut structure CT may not be patterned and remain extended in the D1 direction across the gate structures G2-G4 while thee channel structures CH1 and CH2 with the dummy gate structure 114 are patterned.

After the source/drain patterns 116 and 117 are formed, a 2^{nd} isolation structure 120 may be formed to isolate the source/drain patterns 116 and 117 from one another.

Referring to FIG. 3J, the dummy gate structures 114 patterned in the previous step (FIG. 3I) may be removed along with the sacrificial layers 102 included in the channel structures CH1 and CH2, and gate structures G1-G5 may be formed to surround the patterned channel structures, respectively, followed by planarization, thereby forming the semiconductor device 20 shown in FIGS. 2A-2C.

The removal of the dummy gate structure 114 may performed through, for example, wet etching and/or dry etching, to provide spaces for the gate structures G1-G5. The formation of the gate structures G1-G5 may be performed through, for example, ALD, PVD, CVD, PECVD, a combination thereof, not being limited thereto.

Here, due to the gate-cut structure CT which has already formed, the gate structures G2-G4 may be formed such that the gate-cut structure CT divides the gate structures G21, G31 and G41 from the gate structures G22, G32 and G42, respectively.

When the gate structures G1-G5 are formed, a gate dielectric layer 118 may be first formed to surround the channel layers 104, followed by formation of a work-function metal layer and a gate electrode thereon. Thus, the gate dielectric layer 118 may also be formed on the side surfaces of the gate-cut structure CT which has already been formed before the formation of the gate structures G1-G5.

In the above embodiments, the semiconductor device 20 may be formed on the substrate 101. However, when the substrate 101 is partially or wholly replaced by a backside isolation structure in which a backside power rail and a backside contact structure are formed to connect source/drain patterns of the semiconductor device 20 to a voltage source, a bottom surface of the gate-cut structure CT may be used as an etch stop layer for patterning the substrate 101, according to one or more embodiments.

In the above embodiments, the semiconductor device 20 is formed by nanosheet transistors. However, the disclosure is not limited thereto, and the channel structures including the channel structures CH1 and CH2 of the semiconductor device may be a different type forming a fin-field effect transistor (FinFET) or a forksheet transistor.

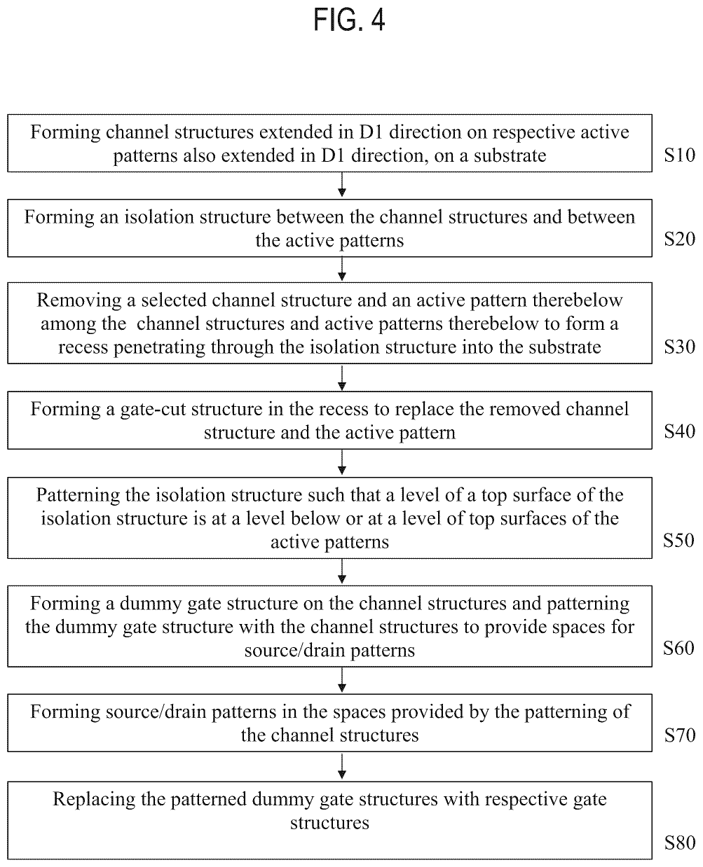

FIGS. 4 illustrates a flowchart of a method of manufacturing a semiconductor device including a gate-cut structure formed at an early step of manufacturing the semiconductor device, according to one or more other embodiments. The method may be described herebelow in reference to FIGS. 3A-3J.

In step S10, a plurality of channel structures extended in the D1 direction may be formed on a plurality of active patterns also extended in the D1 direction on a substrate (FIGS. 3A-3B).

The channel structures and the active patterns may be formed by patterning an initial channel structure epitaxially grown on a substrate such that the active patterns are protruded from a top surface of the substrate, and the channel structures are formed on the active patterns respectively. Here, the initial channel structure may be patterned based on hard mask patterns extended in the D1 direction and arranged in the D2 direction, and thus, the channel structures with the active patterns patterned based on the hard mask patterns may also be extended in the D1 direction.

The channel structures may each be formed of a plurality of sacrificial layers and channel layers alternatingly stacked on the substrate.

In step S20, an isolation structure may be formed between the channel structures and between the active patterns (FIG. 3C).

In step S30, a selected channel structure and an active pattern therebelow among the plurality of channel structures and active patterns therebelow may be removed to form a recess penetrating through the isolation structure into the substrate (FIGS. 3D-3E). The selected channel structure and the active pattern therebelow may be removed by a predetermined length in the 1^{st} direction along which a plurality of gate structure are to be arranged when the semiconductor device is completed.

In step S40, a gate-cut structure may be formed in the recess to replace the removed channel structure and the active pattern (FIG. 3F).

When the gate-cut structure replaces the selected channel structure and the active pattern therebelow which are removed in the previous step (S30), and these channel structure and active pattern have the same structural shape and profile as the other channel structures and respective active patterns therebelow, the gate-cut structure may have the same profile as the channel structures and the respective active patterns therebelow. For example, a width of the gate-cut structure may be the same as a width of the channel structure and a width of the active pattern below the channel structure, at a same level in the D3 direction.

In step S50, the isolation structure may be patterned such that a level of a top surface of the isolation structure is at a level below or at a level of top surfaces of the active patterns (FIG. 3G). Thus, the isolation structure may be formed between the active patterns to be referred to as STI structures.

In step S60, a dummy gate structure may be formed to surround the channel structures and patterned along with the channel structures to provide spaces where source/drain patterns are to be formed (FIG. 3H). Here, the dummy gate structure and the channel structures may be patterned in the D1 direction.

In step S70, source/drain patterns may be formed in the spaces provided by the patterning of the channel structures (FIG. 3I). The source/drain patterns may be epitaxially grown from the channel layers included in the channel structures while the sacrificial layers may be blocked by inner spacers.

In step S80, the patterned dummy gate structures may be removed and respective gate structures may be formed in spaces provided by the removal of the patterned dummy gate structures (FIG. 3J).

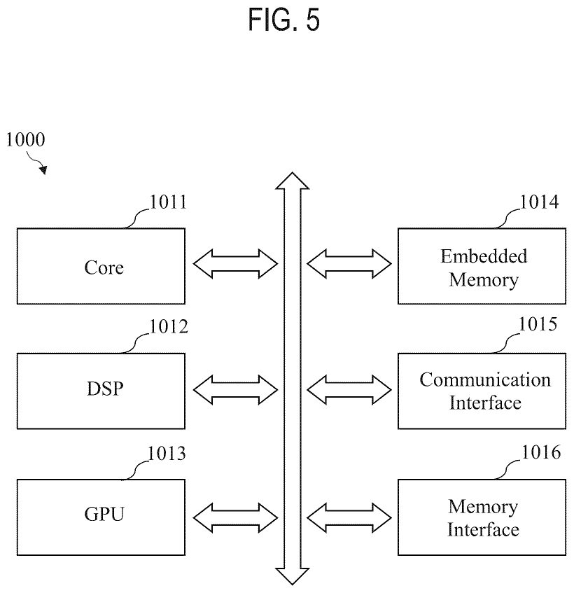

FIG. 5 is a schematic block diagram illustrating an electronic device including a semiconductor device including a gate-cut structure formed at an early step of manufacturing the semiconductor device, according to one or more embodiments. This semiconductor device may be or correspond to the semiconductor device 20 shown in FIGS. 2A-2C.

Referring to FIG. 5, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (RAM) (DRAM), a flash memory, etc.

At least one of the core 211, the DSP 212, the GPU 213, and/or the embedded memory 214 may include the semiconductor device 20 shown in FIGS. 2A-2C.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
a 1^{st} gate structure;
a 2^{nd} gate structure at a side of the 1^{st} gate structure in a 2^{nd} direction crossing a 1^{st} direction;
an isolation structure below the 1^{st} gate structure and the 2^{nd} gate structure in a 3^{rd} direction crossing the 1^{st} direction and the 2^{nd} direction; and
a gate-cut structure between the 1^{st} gate structure and the 2^{nd} gate structure,
wherein a width of the gate-cut structure in the 2^{nd} direction increases in the 3^{rd} direction from a level of a top surface of the 1^{st} gate structure or the 2^{nd} gate structure to a level of a bottom surface of the isolation structure.

2. The semiconductor device of claim 1, wherein the gate-cut structure penetrates through the isolation structure to reach a level below the bottom surface of the isolation structure.

3. The semiconductor device of claim 1, further comprising a substrate on which the isolation structure is formed,
wherein the gate-cut structure penetrates into the substrate.

4. The semiconductor device of claim 3, wherein the width of the gate-cut structure in the 2^{nd} direction decrease in the 3^{rd} direction from a level of a top surface of the substrate to a level of a bottom surface of the substrate.

5. The semiconductor device of claim 1, wherein each of the 1^{st} gate structure and the 2^{nd} gate structure comprises a gate dielectric layer, and
wherein the gate dielectric layer is formed on a side surface of the gate-cut structure.

6. The semiconductor device of claim 1, further comprising:
a substrate;
a 1^{st} active pattern and a 2^{nd} active pattern on the substrate; and
a 1^{st} channel structure on the 1^{st} active pattern, the 1^{st} gate structure on the 1^{st} channel structure; and
a 2^{nd} channel structure on the 2^{nd} active pattern, the 2^{nd} fin structure on the 2^{nd} channel structure,
wherein a width of each of the 1^{st} channel structure and the 2^{nd} channel structure in the 2^{nd} direction increases in the 3^{rd} direction from a top surface to a bottom surface of the 1^{st} channel structure or the 2^{nd} channel structure.

7. The semiconductor device of claim 6, wherein the width of the gate-cut structure is the same as a width of the 1^{st} channel structure or the 2^{nd} channel structure in the 2^{nd} direction, at a same level in the 3^{rd} direction.

8. The semiconductor device of claim 6, wherein the isolation structure is formed between the 1^{st} active pattern and the 2^{nd} active pattern.

9. A semiconductor device comprising:
a 1^{st} channel structure on the 1^{st} active pattern;
a 1^{st} gate structure on the 1^{st} channel structure; and
a gate-cut structure in the 1^{st} gate structure, at a side of the 1^{st} channel structure in a 2^{nd} direction crossing a 1^{st} direction,
wherein the gate-cut structure has a same width as the 1^{st} channel structure in the 2^{nd} direction, at a same level in a 3^{rd} direction crossing the 1^{st} direction and the 2^{nd} direction.

10. The semiconductor device of claim 9, further comprising a 1^{st} active pattern below the 1^{st} channel structure in the 3^{rd} direction,
wherein the gate contact structure has a same width as the 1^{st} active pattern in the 2^{nd} direction, at a same level in the 3^{rd} direction.

11. The semiconductor device of claim 9, further comprising an isolation structure below the 1^{st} gate structure,
wherein the gate-cut structure penetrates through the isolation structure to reach a level below a bottom surface of the isolation structure.

12. The semiconductor device of claim 11, further comprising a substrate on which the isolation structure is formed,
wherein the gate-cut structure penetrates into the substrate.

13. The semiconductor device of claim 11, wherein a top surface of the isolation structure is at a level below or at a level of a top surface of the 1^{st} active pattern.

14. A semiconductor device comprising:
a plurality of gate structures arranged in a 1^{st} direction and extended in a 2^{nd} direction crossing the 2^{nd} direction; and
a gate-cut structure continuously extended in the 1^{st} direction and dividing each of the plurality of gate structures into a 1^{st} gate structure and a 2^{nd} gate structure.

15. The semiconductor device of claim 14, further comprising an isolation structure below the plurality of gate structures,
wherein a width of the gate-cut structure in the 2^{nd} direction increases in a 3^{rd} direction, crossing the 1^{st} direction and the 2^{nd} direction, from a level of a top surface of one of the plurality of gate structures to a level of a bottom surface of the isolation structure.

16. The semiconductor device of claim 15, wherein the gate-cut structure penetrates through the isolation structure to reach a level below the bottom surface of the isolation structure.

17. The semiconductor device of claim 15, further comprising a substrate on which the isolation structure is formed,
wherein the gate-cut structure penetrates through the isolation structure into the substrate.

18. The semiconductor device of claim 17, wherein the width of the gate-cut structure in the 2^{nd} direction decreases in the 3^{rd} direction from a level of a top surface of the substrate to a level of a bottom surface of the substrate.

19. The semiconductor device of claim 14, further comprising:
a substrate;
a 1^{st} active pattern and a 2^{nd} active pattern on the substrate; and
a 1^{st} channel structure on the 1^{st} active pattern, the 1^{st} gate structure on the 1^{st} channel structure; and
a 2^{nd} channel structure on the 2^{nd} active pattern, the 2^{nd} fin structure on the 2^{nd} channel structure,
wherein a width of each of the 1^{st} channel structure and the 2^{nd} channel structure in the 1^{st} direction increases in the 2^{nd} direction from a top surface to a bottom surface of the 1^{st} channel structure or the 2^{nd} channel structure.

20. The semiconductor device of claim 19, wherein the width of the gate-cut structure is the same as a width of the 1^{st} channel structure or the 2^{nd} channel structure in the 2^{nd} direction, at a same level in the 3^{rd} direction.

21-33. (canceled)
